(19) United States
(12) Patent Application Publication
(10) Pub. No.: US 2024/0069165 A1
(43) Pub. Date: Feb. 29, 2024

(54) LENS HOOD INTEGRATION FOR OPTICAL SENSOR TRANSCEIVERS AND SENSOR ASSEMBLY MOUNTING APPARATUS FOR PROCESSING ELECTRONICS

(71) Applicant: LG INNOTEK CO., LTD., Seoul (KR)

(72) Inventor: Bayard G. Gardineer, IV, Princeton, NJ (US)

(73) Assignee: LG INNOTEK CO., LTD., Seoul (KR)

(21) Appl. No.: 18/322,292

(22) Filed: May 23, 2023

Related U.S. Application Data
(60) Provisional application No. 63/400,377, filed on Aug. 23, 2022.
(60) Provisional application No. 63/401,742, filed on Aug. 29, 2022.

(51) Int. Cl. G01S 7/481

(52) U.S. Cl. CPC G01S 7/4813

(57) ABSTRACT

An optical apparatus includes a lens and a lens hood having a tunnel for directing light to the lens. Further, the tunnel includes a first end engaging the lens and a second end spaced from the lens.

### CROSS REFERENCE TO RELATED APPLICATIONS

This application claims the benefit under 35 U.S.C. § 119(e) to U.S. Provisional Application No. 63/400,377, filed on Aug. 23, 2022, and U.S. Provisional Application No. 63/401,742, filed on Aug. 29, 2022, all of which are hereby expressly incorporated by reference into the present application.

### BACKGROUND OF THE INVENTION

### 1. Field of the Invention

The present invention is directed to a lens hood for optical sensor transceivers.

### 2. Description of the Related Art

Autonomous vehicles (AVs) use a plurality of sensors for situational awareness. The sensors, which are part of a self-driving system (SDS) in the AV, include one or more of a camera, lidar (Light Detection and Ranging) device, inertial measurement unit (IMU), etc. Sensors such as cameras and lidar are used to capture and analyze scenes around the AV and to detect objects including static objects such as fixed constructions, and dynamic objects such as pedestrians and other vehicles. Data from such sensors can also be used to detect conditions such as road markings, lane curvature, traffic lights and signs, etc. A scene representation such as 3D point cloud obtained from the AVs lidar can also be combined with images captured by cameras to obtain further insight to the scene or situation around the AV.

In addition, a lidar sensor operating on an AV includes a transceiver apparatus including a transmitter and a receiver assembly. Further, the transmitter transmits the light signal and the receiver receives and processes the received light signal. Without additional optical elements, a transmitter may not properly transmit optical signal at intended targets. Similarly, a receiver may receive the transmitted signal as well as stray light and other light signals. To provide high fidelity object detection and tracking (i.e., minimal or no distortion or noise), an optical sensor such as lidar includes its optical components rigidly fixed while also maintaining sufficient spacing for one or more transceiver assemblies, processing and driver circuitry, cooling elements, cleaning elements, wiring, and associated motor assemblies. In addition, the transceiver components are rigidly fixed with respect to each other and to withstand automotive grade vibrations, high speed rotations for mechanical lidar assemblies, with balance and weight considerations. Additionally, the lidar also includes accommodation packaging and aesthetic considerations must also be considered.

### SUMMARY OF THE INVENTION

Accordingly, one object of the present disclosure is to provide a lens hood for the transmitter and the receiver.

Another object of the present disclosure is to provide a mounting apparatus that provides a rigid structure and has a sufficient housing space for sensor processing circuitry such as a field programmable gate array (FPGA), which is a configurable integrated circuit that assists with digital signal processing of a sensor output (e.g., raw lidar data and the like).

Yet another object of the present disclosure is to provide an integrated lens hood that minimizes divergence of light transmitted from the transceiver apparatus and received by the transceiver apparatus.

Another object of the present disclosure is to provide a mounting apparatus for an optical sensor that provides rigid structure and sufficient housing space for processing circuitry of the optical sensor transceiver.

Another object of the present disclosure is to provide a mounting apparatus for an optical sensor including an FPGA.

To achieve these and other advantages and in accordance with the purpose of the present invention, as embodied and broadly described herein, the present invention provides in one aspect an optical apparatus including a lens; and a lens hood including a tunnel configured to direct light to the lens. Further, the tunnel includes a first end engaging the lens; and a second end spaced from the lens.

The mounting apparatus according to embodiments of the present disclosure is particularly advantageous in minimizing discreet distortions, increasing rigidity and reducing vibrations of the FPGA sensor processing circuitry. The mounting apparatus also provides improved cooling for the FPGA by providing cooling from side walls and bottom walls of the mounting apparatus, while maintaining rigidity and sufficiently small packaging. In addition, the mounting apparatus includes sufficient mass to accept heat generated by electronics within the lidar assembly to dissipate the heat away from the heat-generating components, thereby allowing temperature regulation of the electronic components.

Further scope of applicability of the invention will become apparent from the detailed description given hereinafter. However, it should be understood that the detailed description and specific examples, while indicating embodiments of the invention, are given by way of illustration only, since various changes and modifications within the scope of the invention will become apparent to those skilled in the art from this detailed description.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The present invention will become more fully understood from the detailed description given hereinbelow and the accompanying drawings which are given by way of illustration only, and thus are not limitative of the present invention.

FIG. 1 is a perspective view of a lens hood having a tunnel between an end of the lens and a transmission window according to an embodiment of the present disclosure.

FIG. 2 is another perspective view of a lens hood having a tunnel between an end of the lens and a transmission window with a modified shape according to an embodiment of the present disclosure.

FIG. 3 is a perspective view of a lens hood having a conical shaped tunnel according to an embodiment of the present disclosure.

FIG. 4 is a perspective view of a lens hood having a rectangular shaped tunnel according to an embodiment of the present disclosure.

FIG. 5 is a perspective view of a device including a lens hood and a transmission window according to an embodiment of the present disclosure.

FIG. 6 is a perspective view illustrating the transmission window of FIG. 5.

FIG. 7 is a side perspective view of a FPGA mounting apparatus according to an embodiment of the present disclosure.

FIG. 8 is a side view of the FPGA mounting apparatus of FIG. 7.

### DETAILED DESCRIPTION OF THE INVENTION

The present invention will now be described with reference to the accompanying drawings, wherein the same reference numerals have been used to identify the same or similar elements throughout the several views.

According to some examples, the design considerations for the transmitter and the receiver lens hoods can be different. For example, the lens hood can be designed for the transmitter to create a tunnel between the end of the lens and the transmission window (e.g., an external window of a lidar sensor).

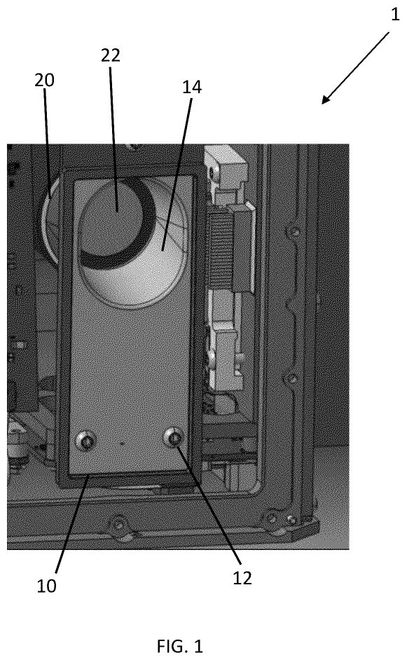

In more detail, FIG. 1 is a perspective view of a device 1 including a lens hood 10 having a tunnel 14 between an end 22 of the lens 20 and a transmission window 34 (e.g., an external window of a sensor like the lidar sensor). The lens hood 10 is attached to a body of the device 1 by fasteners 12, such as screws, bolts or the like. The device 1 can be an electronic sensor, such as a lidar sensor.

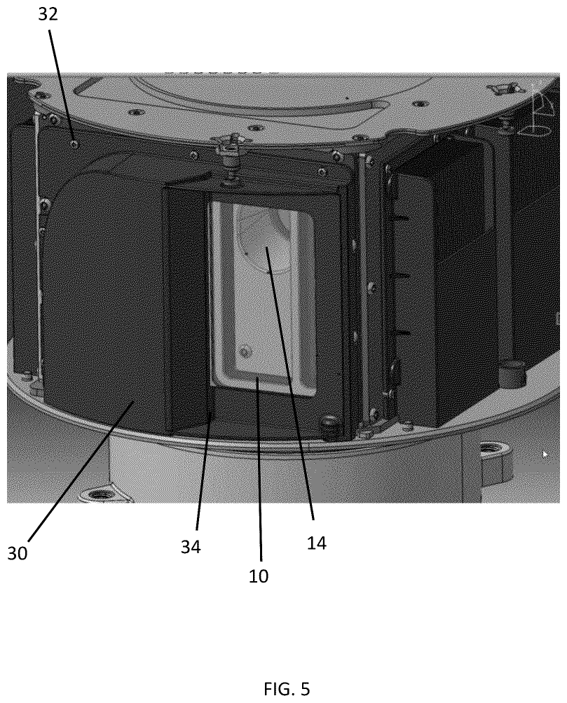

In addition, the tunnel 14 can have an oval cross-section or circular cross-section and can extend to any depth between the end 22 of the lens 20 and the transmission window 34 (see FIG. 5), depending on design constraints and to reduce the divergence of light to and from the device 1. However, the tunnel 14 can have any cross-sectional shape, including a square shape, a rectangular shape, an oval shape, a circular shape, and any type of polygon.

Additionally, the tunnel 14 can have a uniform cross-section throughout its thickness, which is defined as the extension of the tunnel from the end 22 of the lens 20 to the transmission window 34. FIG. 1 illustrates a tunnel 14 that has a substantially uniform cross-section through its thickness, however, the tunnel 14 can have a cross-section that gradually becomes smaller from the transmission window 34 in a direction towards the end 22 of the lens 20.

As one example, the lens hood can be fabricated of a rigid polymer having sufficient strength to withstand mechanical vibrations associated with the sensor operations. For example, the mechanical vibrations can be due to a rotation of a sensor, such as a lidar device.

Further, the lens hoods can be coated with an optically absorbative material to absorb stray light, which can reduce interference, improve signal processing, and focus the transmitted light. Such optically absorbative material includes anti-reflection (AR) coating(s) and can include materials of different thicknesses. Additionally, the lens hoods of the present disclosure can be coated with a plurality of different materials to absorb light, in discrete layers. Also, the coated material can be composed of material designed to absorb certain wavelengths of light transmission. For example, the absorptive material can be designed to absorb material at a predetermined range of wavelengths (e.g., inclusive of the wavelength of the transmitted optical signal). That is, the absorptive material can absorb all other optical signals received that are outside of the predetermined wavelength range, and only allow the desired wavelength to be received at the receiver, thereby reducing interference.

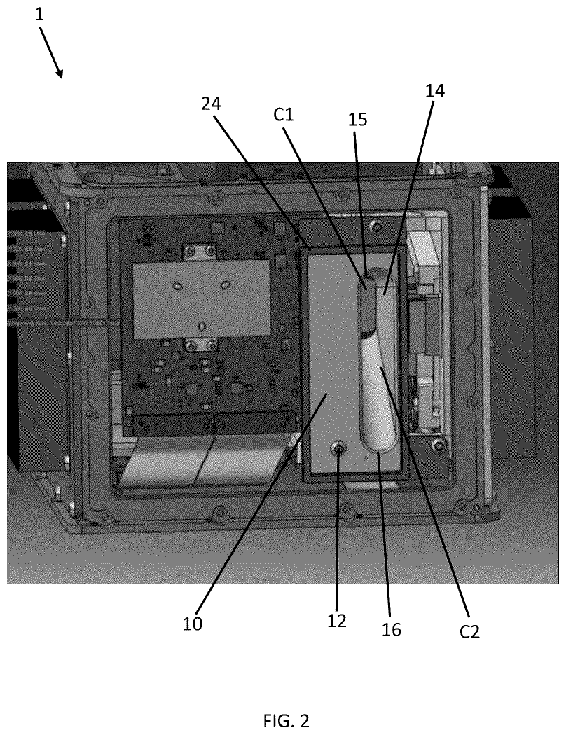

Next, FIG. 2 illustrates is a perspective view of the device 1 including a lens hood 10 having a tunnel 14 between an end 22 of the lens 20 and a transmission window 34 (e.g., an external window of a sensor like the lidar sensor). The tunnel 14 in FIG. 2 has an oval shape (i.e., oval cross-sectional shape) and includes a first end 15 at the end of the lens 20 and a second end 16 at the transmission window 34. The first end 15 of the tunnel 14 can have a smaller cross-sectional profile than the second end 16, and the first end 15 can be located at a distance from a center C2 of the cross-sectional center of the second end 16. FIG. 2 illustrates the tunnel 14 having a decreased size from the second end 16 to the first end 15, where the first end 15 is spaced vertically from the center C2 (i.e., cross-sectional center) of the second end 16. In addition, the first end 15 can also be spaced horizontally from the center C2 of the second end 16, and can have any shape, including a shape that is different from the shape of the second end 16. Further, a center C1 (cross-sectional center) of the first end 15 can be spaced from the center C2 of the second end 16, when viewed from a cross-section of the tunnel 14, and as shown in FIG. 2. Alternatively, the center C1 (cross-sectional center) of the first end 15 can overlap the center C2 of the second end, when viewed from a cross-section of the tunnel 14.

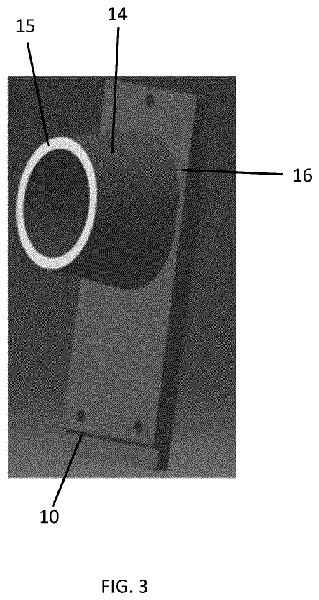

Next, FIG. 3 is a perspective view of a lens hood 10 having a tunnel 14 with a modified shape. In FIG. 3, the tunnel has a conical (i.e., cone) shape, with the first end 15 having a smaller diameter than the second end 16. Each of the first end 15 and the second end 16 can have a circular cross-sectional profile. Further, the tunnel 14 can be provided at any portion (i.e., any location) of the lens hood 10.

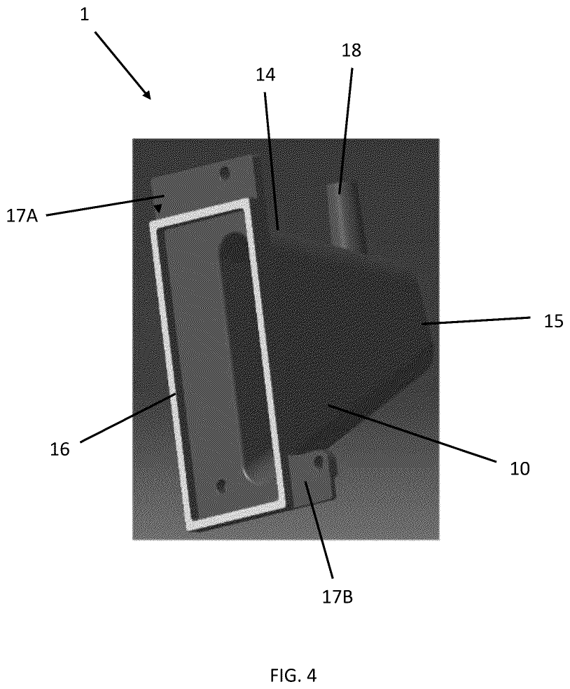

FIG. 4 is a perspective view of a lens hood having a tunnel 14 having a rectangular cross-sectional shape. Further, the lens hood 10 of FIG. 4 can include flanges 17a, 17b for connecting the lens hood 10 to the device 1 (i.e., sensor). In particular, a first flange 17a can be provided at one surface of the lens hood 10, such as a top surface, and a second flange 17b can be provided at another surface of the lens hood 10, such as a bottom side surface, as shown in FIG. 4. However, any number of flanges can be provided to sufficiently secure the lens hood 10 to the rest of the device 1. The lens hood 10 can further include a protrusion 18 for engaging a corresponding hole of the device 1 for securing the lens hood 10 to the device 1. The tunnel 14 of FIG. 4 also illustrates a second end 16 having a larger cross-sectional profile (i.e., dimension) than the first end 15, and the first end 15 can be located at a cross-sectional center of the second end. A size of the tunnel 14 can gradually decrease from the second end 16 to the first end 15.

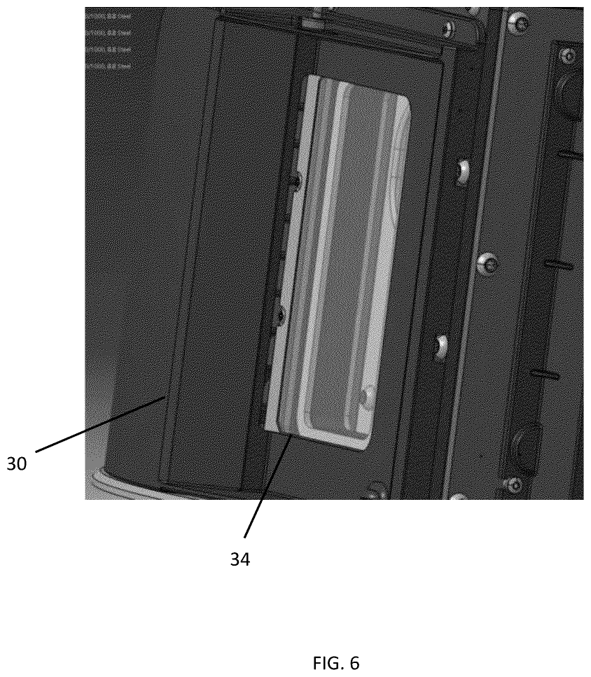

Next, FIG. 5 illustrates a perspective view of a device 1 including a lens hood 10 and a transmission window 34 of a cover member 30, and FIG. 6 is a perspective view illustrating the transmission window of FIG. 5. Fasteners 32 can be used to secure the cover member 30 to the device 1, and the fasteners 32 can include screws, bolts, or the like. Alternatively, the cover member 30 can be fastened or coupled to the device 1 by an adhesive.

As shown, the shape of the lens hoods can eliminate any occlusions at the transmitter and receiver. For example, the receiver lens hood can be designed to eliminate any blind spot or blockage in front of the receiver while also collimating the received light signal and absorbing stray light and other signals. The disclosed lens hood coatings can also act to filter out out-of-phase signals.

In addition, in one example, a vertical array of emitters and receivers is configured to emit light signals through the lens hood. Further, a vertical array of receivers can be arranged in a corresponding fashion to receive return signals. It is also preferable to configure a lens hood to have a vertically oblong shape to correspond to the shape of both of the emitted and returned light signals, as shown in FIG. 2.

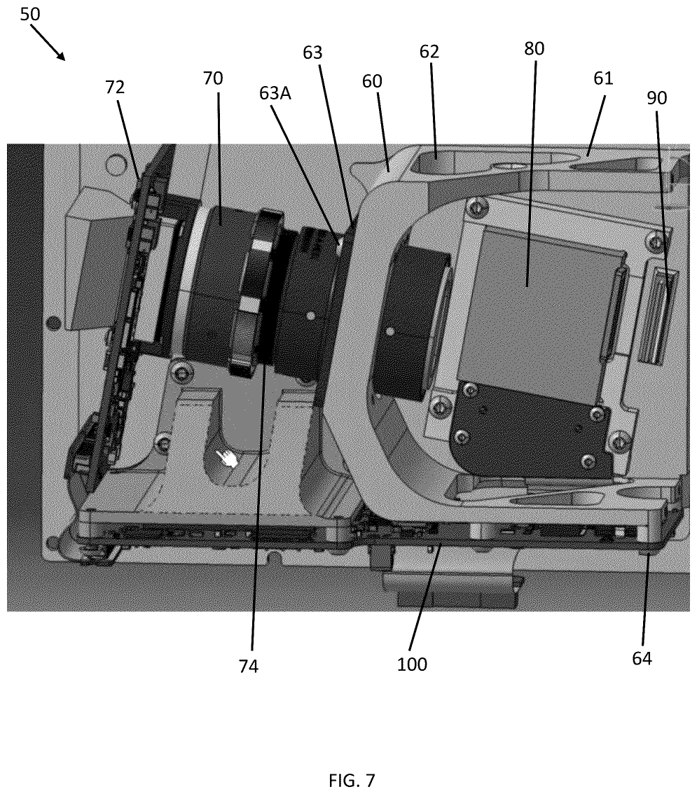

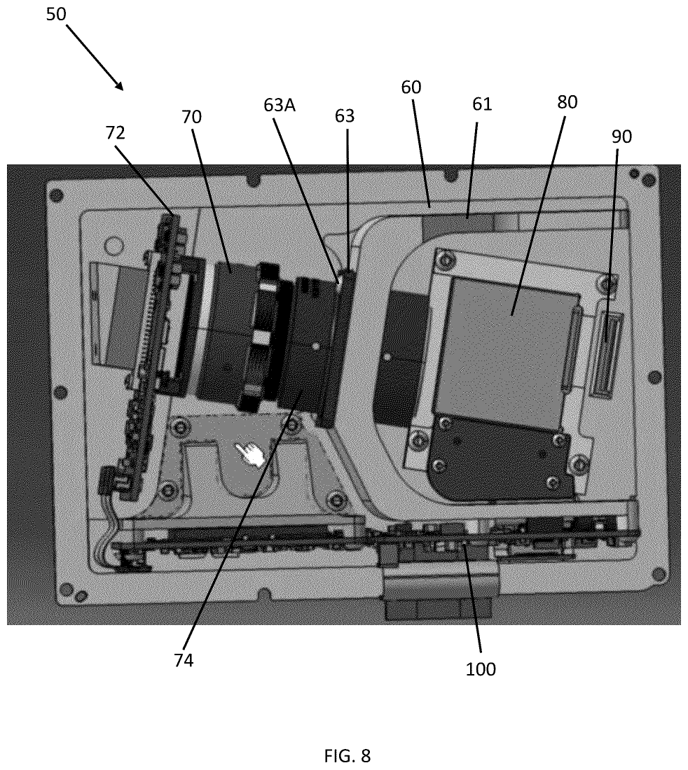

By way of example, one such structure is depicted in FIGS. 7 and 8 as the structure an optical electronic subcomponent. Other aspects of the mounting apparatus 60 can also include an integral mounting structure arranged to secure an electronic device.

For example, as shown in FIGS. 7 and 8, the mounting apparatus 60 (i.e., the FPGA mounting apparatus) can secure an FPGA module 70, a laser module 80 (e.g., laser driver), Tx (transmit) optics 90, a transceiver interface board (e.g., circuit board) 100, to a sidewall of lidar assembly 50. The mounting apparatus 60 can be attached to the circuit board 100 via fasteners 64.

In addition, the Tx optics 90 refers to an output power of the Lidar transceiver. The mounting apparatus 60 may further include a frame 61 and other features to accommodate a variable alignment of the electronic device. For example, the mounting apparatus 60 can include a module mounting structure 63 having a hole (a through-hole) to accommodate the FPGA module 70, and the module mounting structure 63 can be movable in multiple axes to accommodate movement of the FPGA module 70 (e.g., to allow for proper alignment of the FPGA module 70). The module mounting structure 63 can be mounted to the frame 61 of the mounting apparatus 60 via fasteners 63A extending through holes (e.g., apertures, threaded apertures or holes, etc.) of the module mounting structure 63 and the holes of the module mounting structure 63 can be elongated and larger (i.e., have a larger cross-section) than the fasteners to allow for movement of the module mounting structure 63 relative to the mounting apparatus 60. An Li-shaped structure (or L-shaped structure) is shown as oriented laterally and vertically and is provided to secure an optical electronic subcomponent (e.g., the FPGA module 70 or the like, such as any component of a lidar assembly).

The FPGA module 70 can include a circuit board 72 and Rx optics 74. Rx optics 74 refer to a receiver assembly of the lidar assembly 50, and the receiver assembly can receive the transmitted signal as well as stray light and other light signals. Further, the Rx optics 74 can include a lens assembly, as shown in FIGS. 7 and 8.

According to more specific aspects, the mounting apparatus 60 can be provided with a skeleton frame to minimize mass yet still provide structural rigidity in desired regions. A skeleton frame refers to a frame having holes (e.g., through-holes) or apertures 62, as shown in FIG. 7. The holes 62 can have any dimension (e.g., size and shape), and the mounting apparatus 60 shown in FIGS. 7 and 8 includes multiple holes 62 with multiple dimensions to reduce weight of the mounting apparatus 60.

According to another aspect of the present invention, the FPGA mounting apparatus 60 can include a heat-conductive material, such as any type of metal, to transfer heat to walls that are exposed. Additionally, the mounting apparatus 60 can be connected to cooling fins and the like, which allows for heat transfer from the FPGA module 70 to ambient air, thereby providing additional cooling capacity. According to some aspects, the FPGA mounting apparatus 60 can be made of an iron alloy, and aluminum alloy, a magnesium alloy, or the like to help provide reliable structural alignment at manufacturing.

Additionally, the mounting apparatus 60 can further include a fan to direct forced air across an external portion of a sidewall (e.g., the wall onto which the laser module 80 is attached to, as shown in FIGS. 7 and 8) to divert waste heat generated by electronic components. According to some aspects, the FPGA mounting apparatus 60 can also serve as a stabilizing mount for other electronic circuitry, such as laser driver circuits 80, focal plane array circuitry and the like.

In addition, a lidar sensor operating on an AV can include a combination of hardware components (e.g., transceiver apparatus including a transmitter assembly and a receiver assembly, processing circuitry, cooling systems, etc.), as well as software components (e.g. software code and algorithms that generate 3D point clouds and signal processing operations that enhance object detection, tracking, and projection).

Various embodiments described herein may be implemented in a computer-readable medium using, for example, software, hardware, or some combination thereof. For a hardware implementation, the embodiments described herein may be implemented within one or more of Application Specific Integrated Circuits (ASICs), Digital Signal Processors (DSPs), Digital Signal Processing Devices (DSPDs), Programmable Logic Devices (PLDs), Field Programmable Gate Arrays (FPGAs), processors, controllers, micro-controllers, microprocessors, other electronic units designed to perform the functions described herein, or a selective combination thereof. In some cases, such embodiments are implemented by the controller. For a software implementation, the embodiments such as procedures and functions may be implemented together with separate software modules each of which performs at least one of functions and operations. The software code can be implemented with a software application written in any suitable programming language. Also, the software codes may be stored in the memory and executed by the controller.

The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

What is claimed is:

1. An optical apparatus comprising:
a lens; and
a lens hood, the lens hood including a tunnel configured to direct light to the lens,
wherein the tunnel includes:
a first end engaging the lens; and
a second end spaced from the lens.

2. The optical apparatus of claim 1, wherein the lens hood is coated with an optically absorbative material configured to absorb stray light.

3. The optical apparatus of claim 1, wherein the first end of the tunnel has a different cross-sectional size than the second end of the tunnel.

4. The optical apparatus of claim 3, wherein the tunnel decreases in size from the second end to the first end.

5. The optical apparatus of claim 1, wherein the second end tunnel includes a cross-sectional center, and
wherein the first end tunnel is spaced from a cross-sectional center of the second end of the tunnel.

6. The optical apparatus of claim 1, wherein the first end of the tunnel includes a cross-sectional center,
wherein the second end includes a cross-sectional center, and
wherein the cross-sectional center of the first end is spaced from the cross-sectional center of the second end, when viewed from a cross-section of the tunnel.

7. An internal mounting apparatus for an optical sensor, the mounting apparatus comprising:
a contiguous assembly being rigidly connected at a first side to a cooling element, and further being rigidly connected to processing circuitry configured to process output data of the optical sensor,
wherein the contiguous assembly is configured to provide rigid support for the processing circuitry and transfer heat from the processing circuitry to the cooling element.

8. A mounting apparatus comprising:
a module mounting structure having a hole (a through-hole) to accommodate an optical sensor,
wherein the module mounting structure is movable in multiple axes to accommodate movement of the FPGA module.
